(19) United States
(12) Patent Application Publication
(10) Pub. No.: US 2010/0109169 A1
(43) Pub. Date: May 6, 2010

(54) SEMICONDUCTOR PACKAGE AND METHOD OF MAKING THE SAME

(75) Inventors: Ravi Kanth KOLAN, Singapore (SG); Anthony Yi-Sheng Sun, Singapore (SG); Chin Hock Toh, Singapore (SG); Catherine Bee Liang Ng, Singapore (SG); Xue Ren Zhang, Singapore (SG)

Correspondence Address: SUGHRUE MION, PLLC, 2100 PENNSYLVANIA AVENUE, N.W., SUITE 800, WASHINGTON, DC, 20037, US

(73) Assignee: UNITED TEST AND ASSEMBLY CENTER LTD, Singapore (SG)

(21) Appl. No.: 12/431,363

(22) Filed: Apr. 28, 2009

Related U.S. Application Data
(60) Provisional application No. 61/048,644, filed on Apr. 29, 2008.

(51) Int. Cl. H01L 23/28; H01L 21/56

(52) U.S. Cl. 257/787; 438/127; 257/E21.502; 257/E23.116

(57) ABSTRACT

A stiffener is provided for use in making semiconductor devices. The stiffener and method of use provided prevent or reduce warpage of a semiconductor package during the assembly process. More particularly, the stiffener functions to prevent or reduce warpage during molding of an assembly of wafers and/or dies. The stiffener may be positioned above the backside or non-active side of an assembly of wafer and/or dies during molding. The presence of the stiffener prevents or reduces warpage caused by CTE mismatch between the mold material and the wafer and/or under the high temperatures encountered in the process of molding. After molding, the stiffener may continue to provide support to the assembly.

### CROSS-REFERENCE TO RELATED PATENT APPLICATION

The present application claims priority from U.S. Provisional Application No. 61/048,644, which was filed on Apr. 29, 2008, and is incorporated herein by reference in its entirety.

### BACKGROUND OF THE INVENTION

1. Field of the Invention

The present invention relates to the use of a stiffener in making semiconductor devices.

2. Description of the Related Art

One major challenge in semiconductor packaging, for example thru silicon via interconnect 3D packaging, embedded wafer level packaging and other semiconductor packaging involving handling of thin wafer or chips, is warpage, as the structures are susceptible to warpage after a molding process. This warpage results due to Coefficient of Thermal Expansion (CTE) mismatch between the mold compound and the Silicon wafers or chips.

One method of ameliorating the problem is to bond a temporary support carrier to the wafer or chips before continuing with assembly processes such chip stacking and molding. The support carrier adds thickness and mechanical strength to the structure to render the structure less susceptible to warpage. The support carrier is removed after molding.

Whilst the support carrier is capable of ameliorating the warpage, there is still a desire to further improve the degree of warpage.

An alternative method that can avoid the use of the temporary support carrier is also desired, as the carrier can have the following drawbacks:
The cost of the wafer carrier support system is usually very high.
The wafer carrier support system's adhesive may not be compatible with some of the processes, such as the ability to withstand reflow temperature when stacking the chips with through silicon interconnects.
De-bonding the support carrier from the chips after molding may damage the chips.

There is therefore a need to provide a semiconductor package and method of making the package, that can address one or more of the problems outlined above.

### SUMMARY OF THE INVENTION

The present invention provides a sacrificial stiffener to prevent or reduce warpage of a semiconductor package during the assembly process. More particularly, the stiffener functions to prevent or reduce the warpage occurring during molding of an assembly of wafers and/or dies.

According to an aspect of the invention, a method for forming semiconductor packages is provided, the method comprising: attaching disposing one or more semiconductor chips to on a front top side of a wafer; positioning disposing a stiffening layer above the semiconductor chips; and molding the semiconductor chips with a molding material between the stiffening layer and the wafer.

The method may further comprise: curing the molding material; wherein the stiffening layer provides support to the package during the curing.

The method may be provided wherein the stiffening layer is silicon

The method may be provided wherein the stiffening layer directly contacts the semiconductor chips.

The method may be provided wherein a thermally conductive layer is provided between the stiffening layer and the top surface of the semiconductor chips.

The method may be provided wherein a temporary adhesive is provided on the surface of the stiffening layer facing the semiconductor chips.

The method may be provided wherein the stiffening layer is completely removed from the molding material.

The method may be provided wherein the removing is performed by mechanical grinding or chemical etching.

The method may be provided wherein the stiffening layer is partially thinned.

The method may be provided wherein the thinning is performed by mechanical grinding or chemical etching.

The method may be provided wherein the stiffening layer covers a top side of the molding material only on a periphery of the wafer is in the shape of a ring.

The method may be provided wherein the stiffening layer is in the shape of a ring.

The method may be provided wherein the stiffening layer is in the shape of a square or a rectangle.

The method may be provided wherein the stiffening layer substantially covers a top side of the molding material.

According to a further aspect of the invention, a semiconductor package is formed according to the method(s) described above.

The method may further be provided wherein the stiffening layer is removed by singulating semiconductor die packages on the wafer.

According to a further aspect of the invention, a method for forming semiconductor packages is provided, comprising: disposing one or more semiconductor chips on a top side of a wafer; disposing a stiffening layer in contact with the top side of the wafer only on the periphery of the wafer; and molding the semiconductor chips with a molding material, the molding material being bounded by an inside-facing surface of the stiffening layer at the periphery of the wafer.

The method may further comprise: curing the molding material; wherein the stiffening layer provides support to the package during the curing.

The method may be provided wherein the stiffening layer is silicon or glass.

The method may be provided wherein the stiffening layer is in the shape of a ring.

The method may be provided wherein the stiffening layer is in the shape of a square or a rectangle.

According to a further aspect of the invention, a semiconductor package is provided, comprising: a semiconductor chip disposed on a top side of a portion of a wafer; and a molding material encapsulating at least the sides of the semiconductor chip, the molding material having been molded between the portion of the wafer and a stiffening layer disposed over the molding material.

The described stiffening layer may be one which substantially covers the molding material, or which directly contacts the surface of the semiconductor chips. The stiffening layer may also have been completely removed from the semiconductor package.

The semiconductor package may be provided such that the molding material completely encapsulates the semiconductor chip, the molding material having been molded between the portion of the wafer and a stiffening layer disposed over the molding material only at the periphery of the wafer.

The described stiffening layer may have been completely removed by singulation of the semiconductor package.

According to a further aspect of the invention, a semiconductor package is provided, comprising: a semiconductor chip disposed on a top side of a portion of a wafer; and a molding material encapsulating at least the sides of the semiconductor chip, the molding material having been molded in an area above the portion of the wafer bounded by an inside surface of a stiffening layer disposed over the molding material.

The described stiffening layer may have been completely removed by singulation of the semiconductor package.

### BRIEF DESCRIPTION OF THE DRAWINGS

The above and other features of the present invention will become more apparent by describing in detail exemplary embodiments thereof with reference to the attached drawings in which:

FIGS. 1(A)-1(P) illustrate a process of making semiconductor device according to exemplary embodiments of the invention;

packages.

FIGS. 2(A)-2(J) show exemplary embodiments of semiconductor

FIGS. 3(A)-3(D) show processes using a stiffener according to various exemplary embodiments.

FIGS. 4(A)-4(J) show exemplary embodiments of semiconductor packages which can be formed from the process as described in FIGS. 3(A) to 3(D).

FIGS. 5(A)-5(F) show a further exemplary embodiment of a semiconductor device having a stiffener in ring form.

FIGS. 6(A)-6(F) show yet another exemplary embodiment of a semiconductor device having a stiffener in ring form.

### DETAILED DESCRIPTION OF THE EXEMPLARY EMBODIMENTS

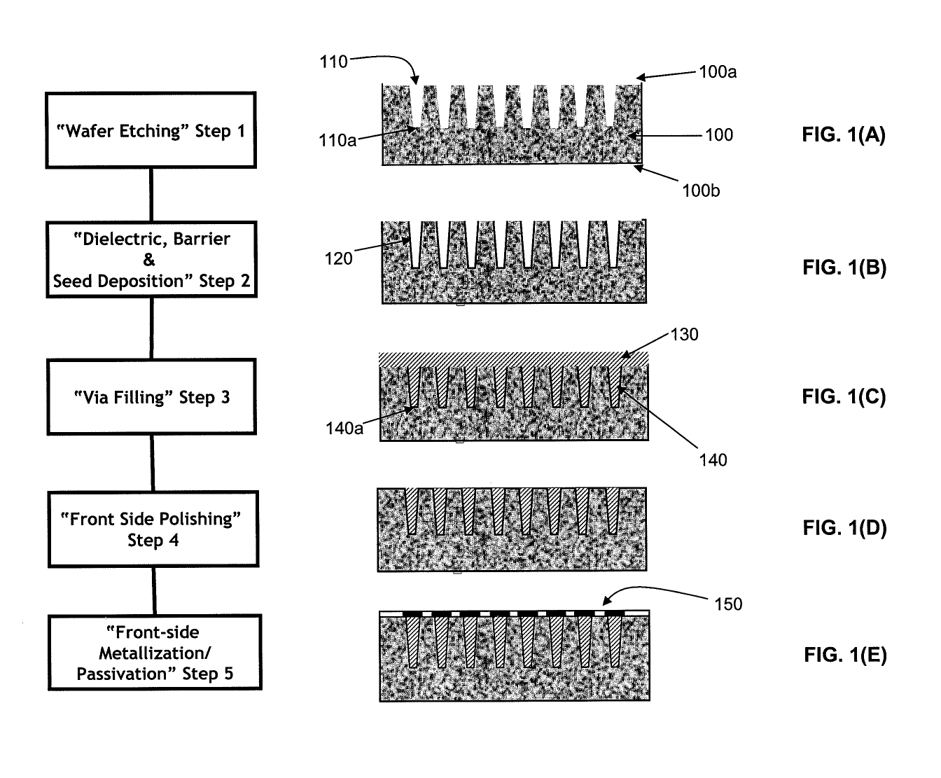

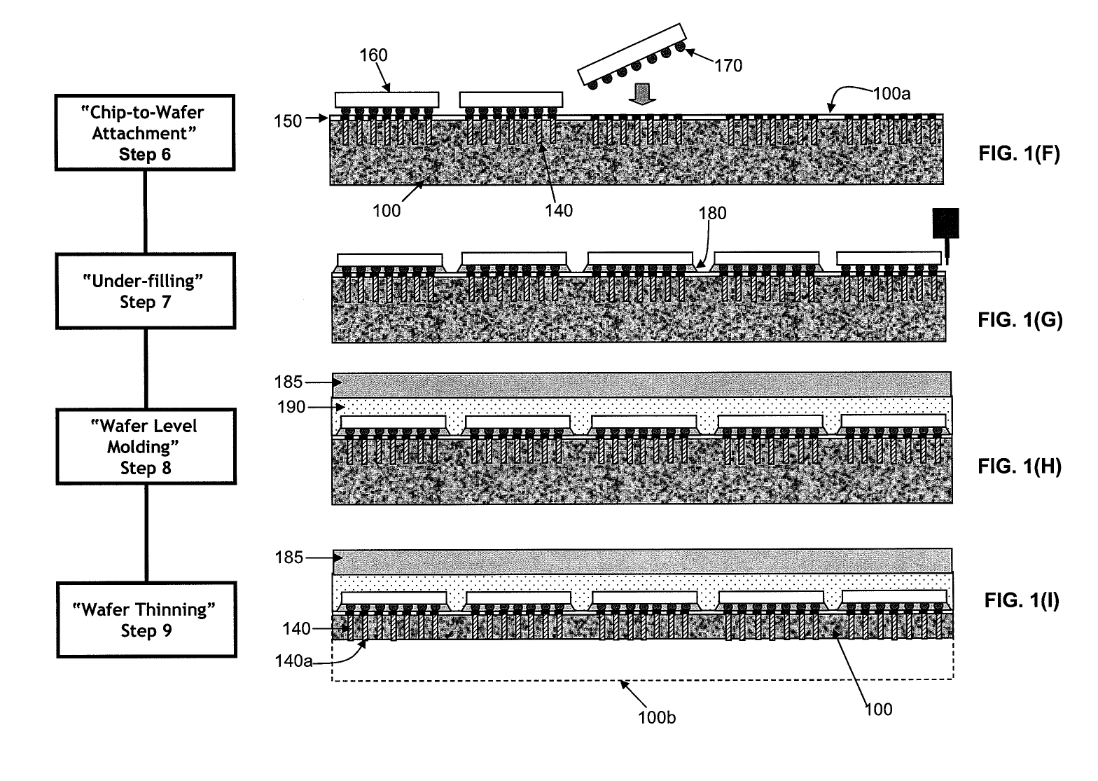

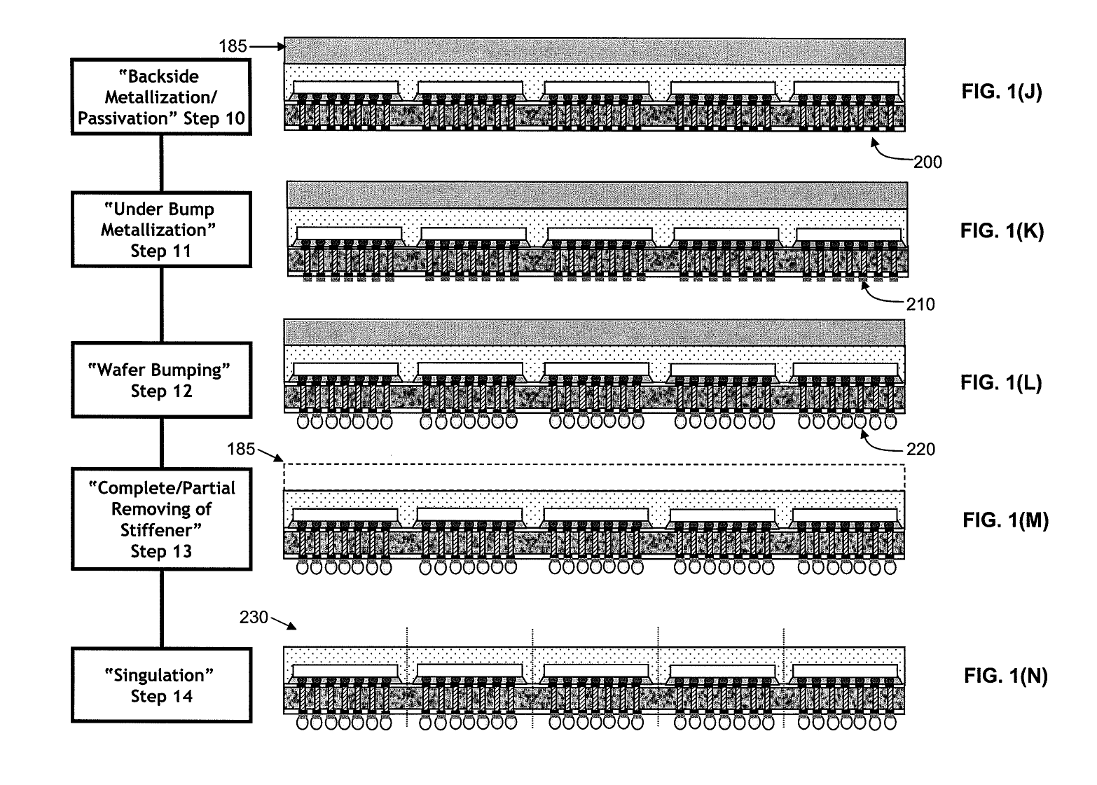

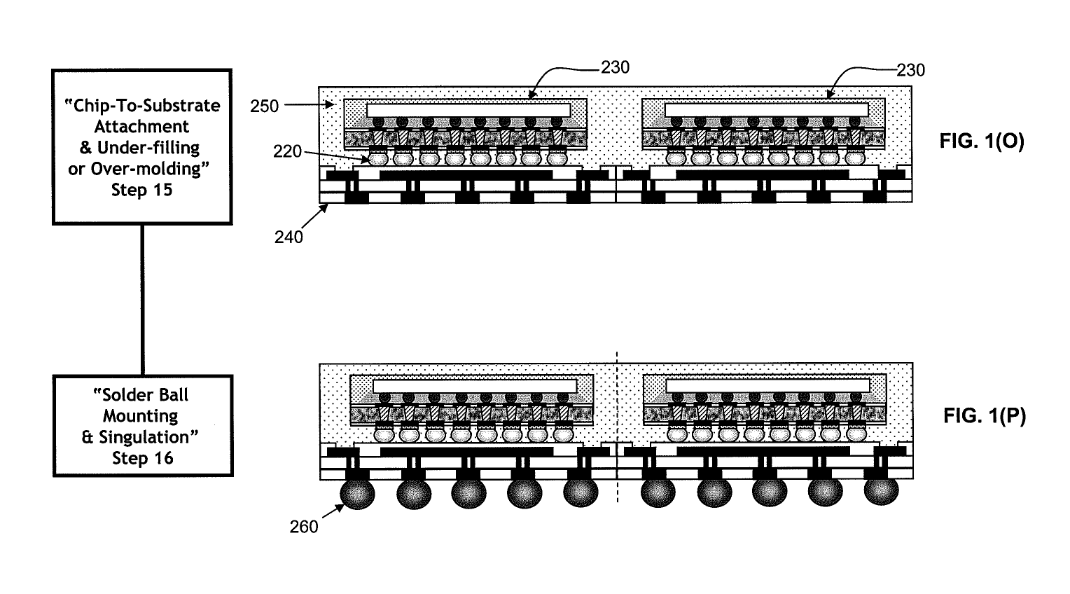

### FIGS. 1(A) to 1(P)

A process of making a semiconductor device is described with reference to FIGS. 1(A) to 1(P).

“Wafer Etching” Step 1: As shown in FIG. 1(A), a wafer 100 is etched to create one or more vias 110 in the wafer 100. The wafer can be an inactive silicon wafer without active circuitry embedded therein, or an active silicon wafer with active circuitry embedded therein. Where the wafer is an active wafer, it would result in a functional die in the resulting semiconductor package. Where the wafer is an inactive wafer, it would function as an interposer between the chip stacked above and the substrate below. For example, the interposer can distribute finer pitch connections of the chip stacked above to larger pitch connections of the substrate below. The etching can be achieved by patterning a mask (not shown) onto a front side 100a of the wafer 100. The mask exposes areas of the front side 100a of the wafer 100 where the vias 110 are to be formed and covers the remaining areas. Etching, for example, deep reactive-ion etching (DRIE), is then performed to form the vias 110 in the wafer 100. The mask is removed after the etching is completed. Other etching technique includes but not limited to laser drilling. The vias 110 extend from the front surface 100a of the wafer 100 toward a rear surface 100b such that their end portions 110a reside partially in the wafer 100.

“Dielectric, Barrier & Seed Layer Deposition” Step 2: The etched wafer 100 from Step 1 is plated with a dielectric layer, followed by a barrier metal layer over the dielectric layer, and followed by a seed layer over the barrier metal layer, as shown in FIG. 1(B). The dielectric layer is usually silicon dioxide. The barrier metal layer may be Titanium, Titanium Nitride (TiN) or tantalum silicon nitride. The seed layer may be copper or any other metal. For ease of illustration, the dielectric layer, the barrier metal layer and the seed layer are collectively given the numeral 120 in the drawings.

“Via Filling” Step 3: Referring to FIG. 1(C), the wafer 100 from Step 2 is further plated with a metallic material 130 to fill the vias 110 with the metallic material 130 and hence form through silicon interconnects 140. Accordingly, the end portions 110a of the vias 110 will now be referred to as end portions 140a of the through silicon interconnects 140. The metallic material may, for example, be copper, tungsten or polysilicon.

“Front Side Polishing” Step 4: As depicted in FIG. 1(D), the wafers 100 from Step 3 may undergo a polishing process such as chemical mechanical polishing to remove any residual metallic material 130 (e.g., copper) on the front side 100a of the wafer 100 where the vias 110 are formed.

“Front Side Metallization/Passivation” Step 5: Front side metallization and passivation are carried out on the wafers 100 from Step 4 as shown in FIG. 1(E). As used herein, the “front side” refers to the surface of the wafer 100 where the vias 110 are formed and the “back side” refers to the opposite surface of the wafer 100. The metallization process involves patterning metal traces and/or bond pads on top or front side 100a of the wafer 100 and the through silicon interconnects 140. The metallic layer used in patterning the metal traces and/or bond pads may be copper, aluminum or other metals. The passivation process coats areas on the front side of the wafer, which are not covered by the metallization layer, with a passivation layer such as silicon nitride, silicon dioxide, polyimide, benzocyclobutene (BCB) or a photosensitive epoxy resin (trade names: “WPR-1020”, “WPR-1050” or “WPR-1201”, products of JSR Micro, Inc.). For ease of illustration, the front side metallization and passivation layers are collectively given the numeral 150 in the drawings.

“Chip-to-Wafer Attachment” Step 6: Referring to FIG. 1(F), one or more semiconductor chips 160, each provided with a pattern of conductive bumps 170 such as solder bumps, are positioned over the front surface 100a of the wafer 100 such that the conductive bumps 170 of the semiconductor chips 160 are aligned and are in contact with the through silicon interconnects 140 of the wafer 100. The one or more semiconductor chips 160 may be obtained by dicing a bumped wafer (not shown). The conductive bumps 170 of the semiconductor chips 160 are then reflowed to result in attachment of the chips 160 to the wafer 100.

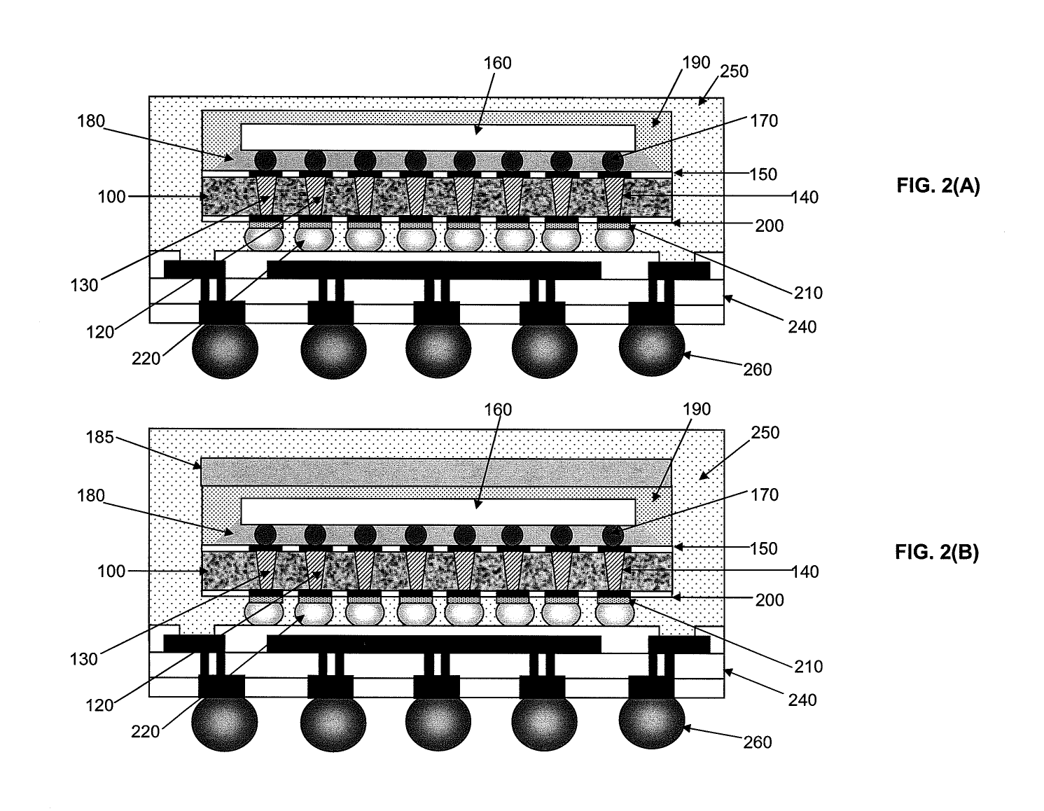

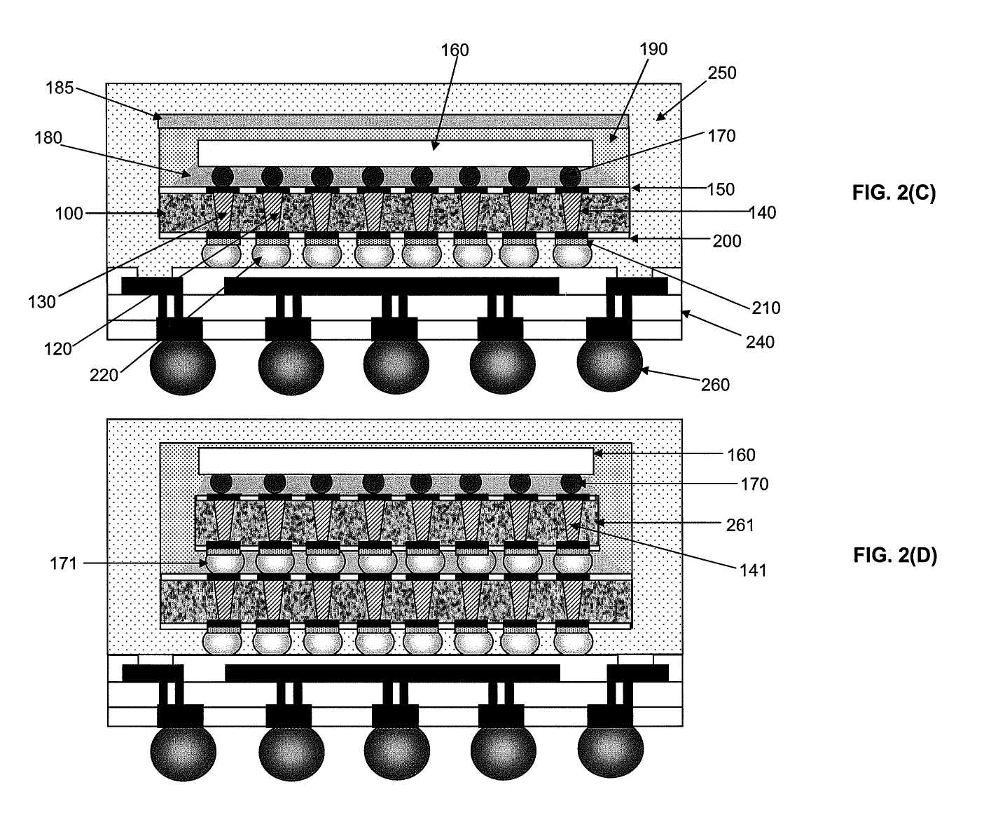

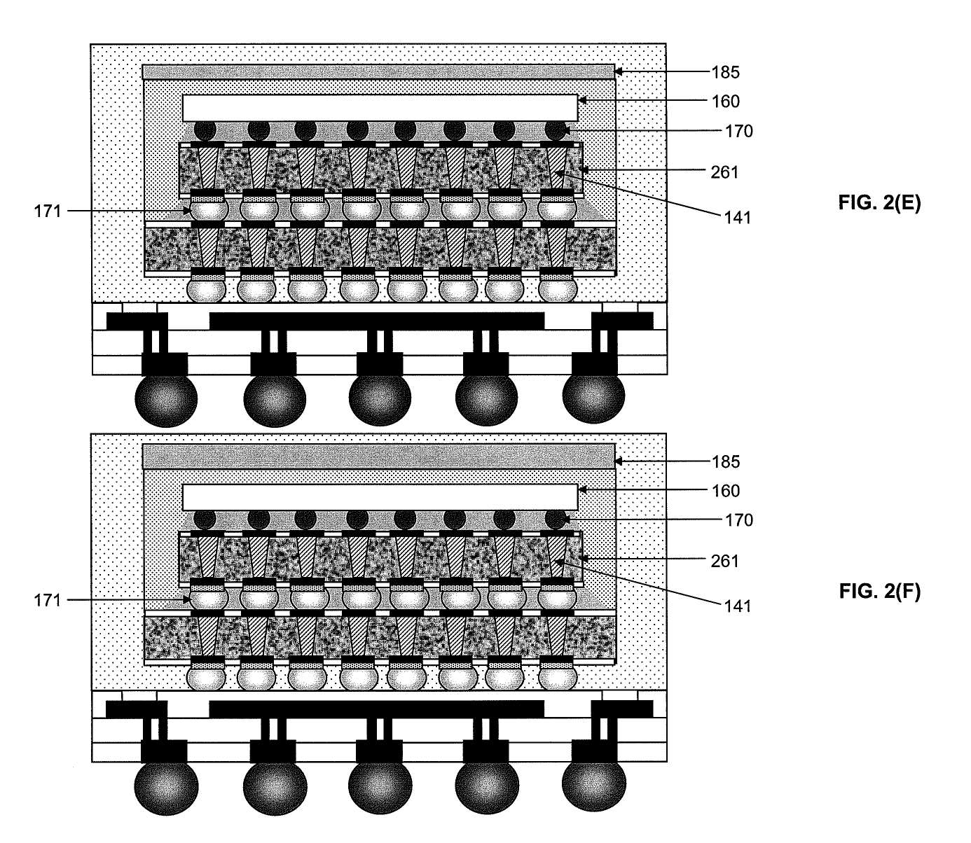

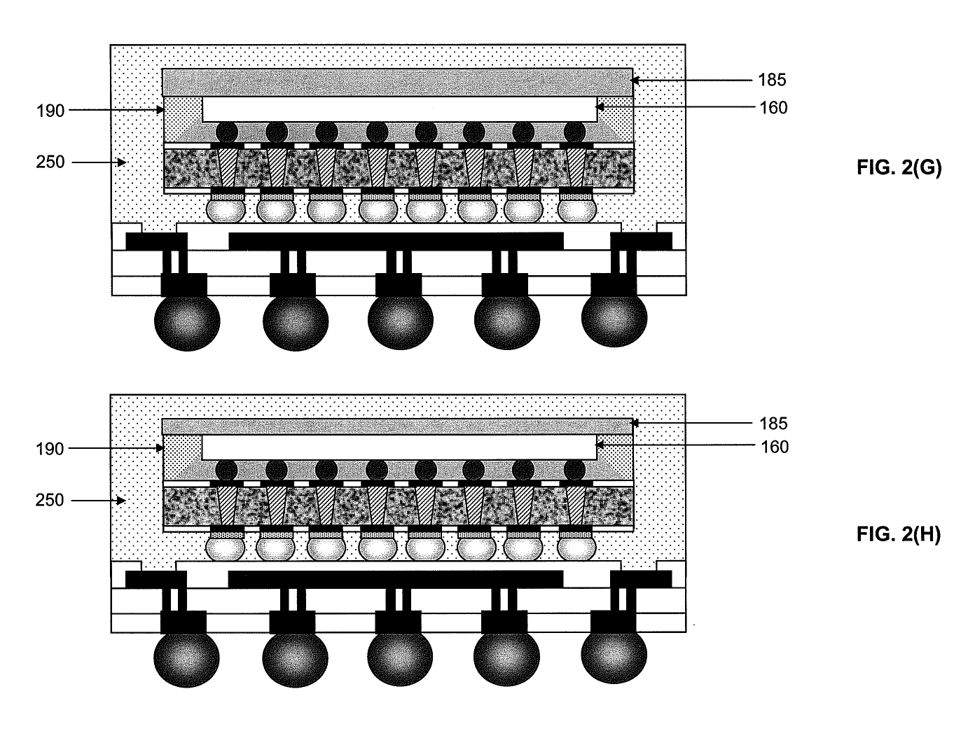

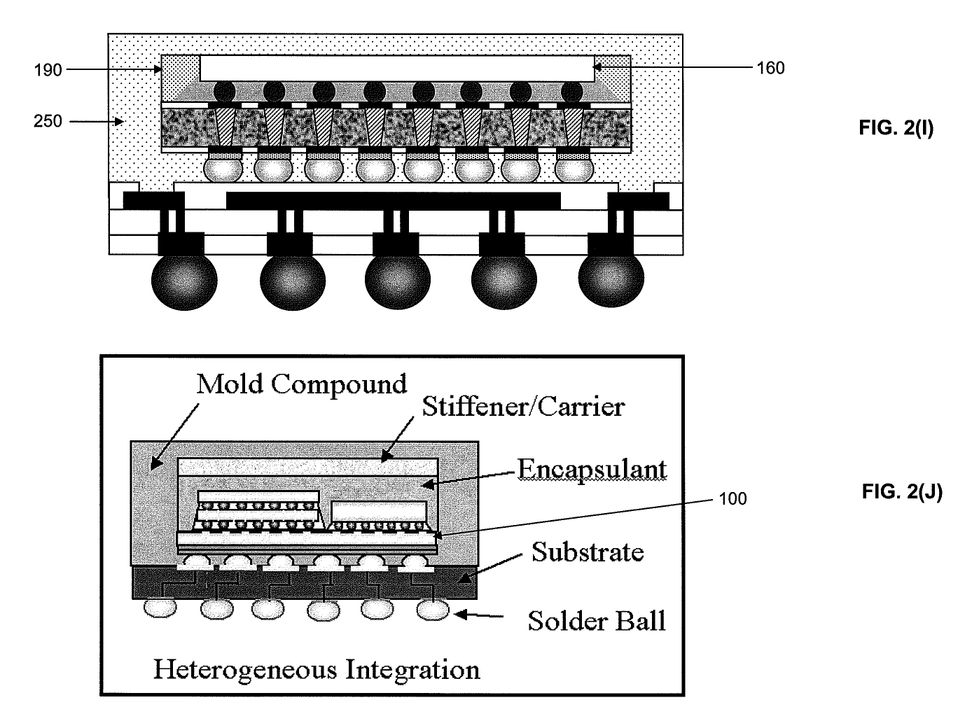

It will be appreciated that the process can be extended to a 3 or more die stack package by inserting one or more chips with through-silicon interconnects 140 and conductive bumps 220 between the wafer 100 and the chip 160. Exemplary embodiments of semiconductor packages with 3 stacked dies are shown in FIGS. 2(D) to 2(F).

Likewise, the process can be extended to heterogeneous structures such as the exemplary embodiment of a final package shown in FIG. 2(J). In such a package, the arrangement of dies can vary along the length of the wafer 100. For example, in the context of FIG. 2(J), a vertical stack comprising a TSI chip and a flip chip is mounted on one part of the wafer 100 and a single flip chip is mounted adjacent to the vertical stack on the wafer 100.

“Underfilling” Step 7: With reference to FIG. 1(G), the gaps between the chips 160, the conductive bumps 170 and the front side 100a of the wafer 100 are underfilled with an underfill material 180 such as an epoxy resin or other materials such as polymer-based encapsulation materials.

“Wafer Level Molding” Step 8: The wafer 100 and the chips 160 are covered with mold material 190 such as an epoxy resin or polymer-based encapsulation material as shown in FIG. 1(H). Before the molding process is carried out, a stiffener 185 is first positioned above the chips 160. During molding, the mold material 190 will flow into the space between the stiffener 185 and the chips 160 to encapsulate the chips 160. As the mold material 190 cures under heat, the stiffener 185 can prevent the structure from warping resulting from differential thermal expansions of the various components in the structure. The stiffener 185 may be made of silicon, glass or other materials suitable for preventing the warpage.

The stiffener 185 may also be mounted directly on the chips 160 such that it is in direct contact with the chips 160. An exemplary final package depicting the stiffener in direct contact with the chip 160 is shown in FIGS. 2(G) and 2(H). There may also be provided a thermally conductive layer (not shown) such as thermally conductive epoxies or thermal grease between the stiffener 185 and the top surface of the chips 160 to improve thermal dissipation.

“Wafer Thinning” Step 9: As shown in FIG. 1(I), the molded wafer 100 from Step (8) is ground and polished at its backside 100b to expose end portions 140a of the through silicon interconnects 140. As will be appreciated, the grinding may be achieved by mechanical grinding methods or chemical etching methods.

“Back Side Metallization/Passivation” Step 10: Referring to FIG. 1(J), back side metallization and passivation are carried out on the thinned wafers 100 from Step 9. The metallization process patterns metal traces and/or bond pads over the back side 100b of the wafer and end portions 140a of the through silicon interconnects 140. The metallic layer used in patterning the metal traces and/or bond pads may be copper, aluminum or other metals. The passivation process coats at least the areas on the back side of the wafer, which are not covered by the metallization layer, with a passivation layer such as silicon nitride, silicon dioxide, polyimide, benzocyclobutene (BCB) or a photosensitive epoxy resin (trade names: “WPR-1020”, “WPR-1050” or “WPR-1201”, products of JSR Micro, Inc.). For ease of illustration, the backside metallization and the passivation layers are collectively given the numeral 200 in the drawings.

“Under bump metallization” Step 11: Under bump metallization (UBM) pads 210 are formed on selected areas of the metallized portions of the wafer 100 from Step 10 as depicted in FIG. 1(K). The selected areas may be locations for mounting conductive bumps 220 in subsequent step 12. The UBM pads 210 may be made of Al/Ni/Au, Al/Ni—V/Cu, Cu/Ni/Au, Cu/Ni/Pd, Cu/Cr/Al, Ti—W/Cu/Ni(EP)/Cu(EP), Cr/Cu/Cu(EP)/Ni(EP), Ti/Ni(EP) or Ti/Ai/Ti/NiV.

“Wafer Bumping” Step 12: With reference to FIG. 1(L), the UBM pads 210 at the back side 100b of the wafer 100 are provided with conductive bumps 220 such as solder interconnects. Other non-solder interconnects include but are not limited to Copper pillars, Gold studs, etc.

“Complete/Partial Removing of Stiffener” Step 13: As shown in FIG. 1(M), the stiffener 185 is completely removed from the mold material 190 by methods such as mechanical grinding or chemical etching.

Although not shown in the FIG. 1(M), the stiffener 185 may also be partially thinned or be retained. The partial thinning of the stiffener may also be achieved by mechanical grinding or chemical etching methods.

If the stiffener 185 is intended to be completely removed, an alternative method would be to have a temporary adhesive on the surface of the stiffener 185 in contact with the mold material 190 such that the stiffener 185 can be dislodged or de-bonded in entirety from the mold material when required.

“Singulation” Step 14: The bumped wafer and chip structure from Step 13 is singulated into individual units 230, each unit comprising the singulated wafer and chip as shown in FIG. 1(N). Alternatively, the singulation may be such that the individual units comprises more than one singulated wafer and chips.

“Chip-to-Substrate Attachment and Under-filling or Over-molding” Step 15: As depicted in FIG. 1(O), the singulated units 230 are attached to a substrate 240 by reflowing the solder interconnects 220 at the backside 100b of the wafer 100. The mounted units 230 are over-molded with a molding material 250 such as an epoxy resin or polymer-based encapsulation material. Alternatively, the molding material 250 may encapsulate the units 230 such that the top surface of the stiffener (if partially thinned or retained) or the top surface of the chip 160 (if the stiffener is removed) is exposed. The substrate 240 may be an organic/laminate substrate.

“Solder Ball Mounting and Singulation” Step 16: The underside of the substrate 240 is provided with external electrical connections 260 such as solder balls as illustrated in FIG. 1(P). The entire assembly is then singulated to form individual semiconductor packages.

### FIGS. 2(A) to 2(F)

As mentioned in the description for Step 13, the stiffener 185 may be completely removed, partially removed or retained.

FIG. 2(A) shows a semiconductor package which can be formed from the above described process or other suitable processes whereby the stiffener 185 is completely removed.

FIG. 2(B) shows a semiconductor package which can be formed from the above described process or other suitable processes whereby the stiffener 185 is retained.

FIG. 2(C) shows a semiconductor package which can be formed from the above described process or other suitable processes whereby the stiffener 185 is partially removed or partially thinned. An advantage of having the stiffener 185 partially thinned is that the mold material 250 can be better adhered to the singulated units 230, particularly when the stiffener 185 is made from silicon.

FIGS. 2(D) to 2(F) show exemplary semiconductor packages that can be made from the above described process with modifications to extend to a 3 or more die stack package. For such packages, instead of attaching flip chips 160 to the wafer 100, a plurality of chips 161 with through-silicon interconnects 141 and conductive bumps 171 may be mounted onto the wafer 100 in a vertical manner in the “Chip-to-Wafer Attachment” Step 6. The top-most die/chip can also be the chip 160 with conductive bumps 170 as described in Step 6 above.

FIG. 2(D) shows a semiconductor package in which the stiffener 185 is completely removed, FIG. 2(E) shows a semiconductor package in which the stiffener 185 is partially removed or partially thinned, and FIG. 2(F) shows a semiconductor package in which the stiffener 185 is retained.

FIGS. 2(G) to 2(I) show further exemplary semiconductor packages that can be made from the above described process with modifications to mount the stiffener 185 directly on the top-most chip 160 as previously mentioned in the description for Step 8 “Wafer Level Molding”. For such packages, instead of leaving a space between the top-most chips 160 and the stiffener 185, the stiffener is in contact with the top surface of the chips 160 (optionally through a thermally conductive layer) such that the mold material 190 does not encapsulate the top surface of the chip. The stiffener 185 can therefore function as a heat sink which can conduct heat generated by the chips 160 during operation. Likewise, should the stiffener 185 be completely removed to expose to the top surface of the chips 160, the absence of mold material 190 would also enhance the heat dissipating properties of the package.

FIG. 2(G) shows a semiconductor package in which the stiffener 185 is retained and is in contact with the chip 160, FIG. 2(H) shows a semiconductor package in which the stiffener 185 is partially removed or partially thinned and is in contact with the chip 160, and FIG. 2(I) shows a semiconductor package in which the stiffener 185 is completely removed to expose top surface of the chips 160 to mold material 250.

FIG. 2(J) shows an exemplary semiconductor package having a heterogeneous structure. As previously described, such a package can be assembled by the process as described above by arranging the TSI chips and flip chips in the required orientation during the “Chip-to-Wafer Attachment” Step 6.

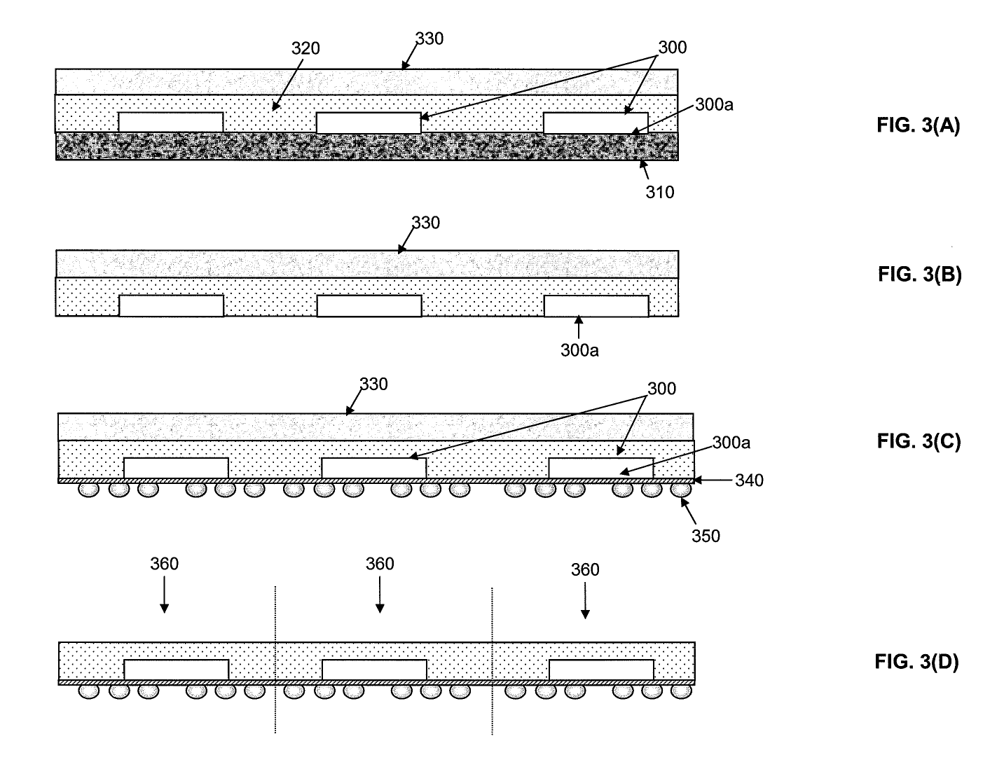

### FIGS. 3(A) to 3(D)

In addition to the above described processes and semiconductor packages, the use of the stiffener can be extended to processes of making packages of other types of structures.

FIGS. 3(A) to 3(D) show another process in which the stiffener can be used.

FIG. 3(A) shows an array of chips 300 mounted with their active side 300a facing a support carrier 310 and being overmolded with mold material 320. The support carrier 310 can, for example, be an inactive silicon wafer. A stiffener 330 is positioned above the chips 300 prior to molding such that the assembly does not warp during the molding process.

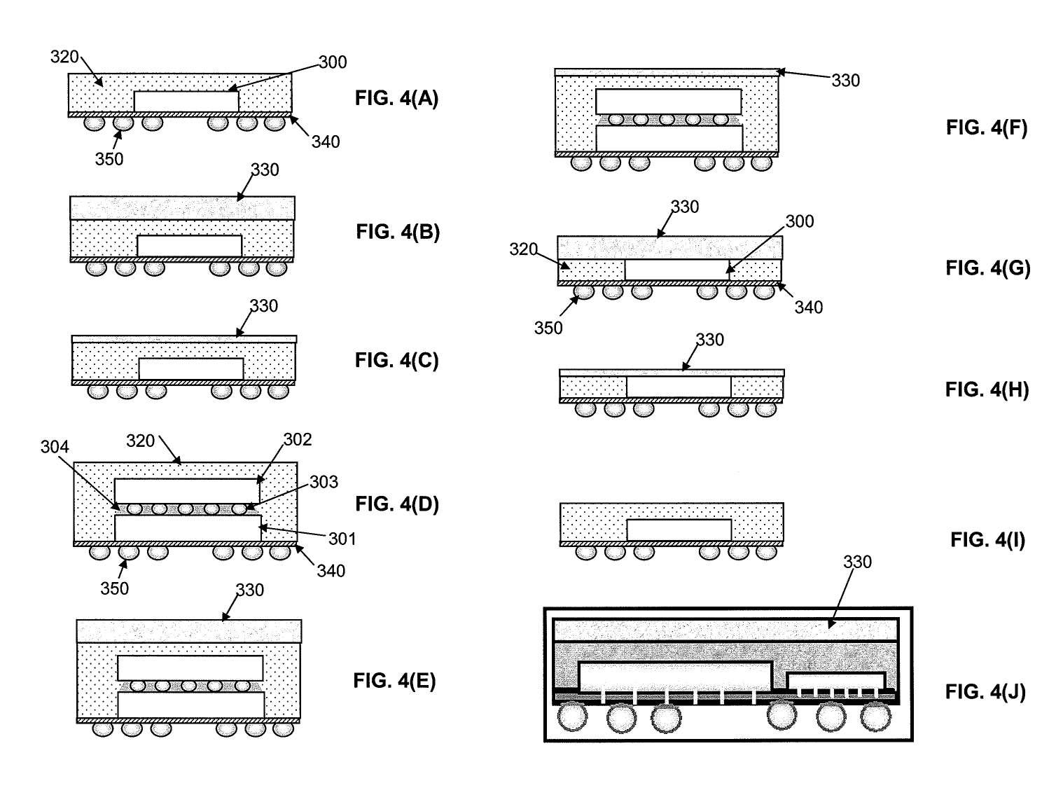

Although not shown in FIG. 3(A), the arrangement of the chips 300 can be in vertical stacks of one or more chips with Thru-Silicon Interconnects (TSI) or can be in a heterogeneous manner such as alternating between stacked TSI chips and single flip chips or alternating between chips of different sizes as shown in FIG. 4(J).

The support carrier 310 is subsequently de-bonded from the array of chips 300 as shown in FIG. 3(B) to expose the active sides 300a of the chips 300.

Referring to FIG. 3(C), metallization, passivation and under bump metallization are carried out (similar to Steps 10-12 above) on the active side 300a of the chips 300. For ease of illustration, the metallization, passivation and under bump metallization layers are collective referred to as numeral 340 in the drawings. Following this, conductive bumps 350 are formed which can be in a fan-out or fan-in arrangement. In FIG. 3(C), a fan-out arrangement is shown (i.e., conductive bumps spread out beyond the periphery of the chip 300).

The stiffener 330 is either removed completely, partially thinned/removed or retained in the assembly using methods as described above. Finally, the assembly is singulated into single units 360.

### FIGS. 4(A) to 4(J)

FIGS. 4(A) to 4(C) show exemplary semiconductor packages which can be formed from the process as described in FIGS. 3(A) to 3(D).

FIG. 4(A) shows a semiconductor package in which the stiffener 330 is completely removed, FIG. 4(B) shows a semiconductor package in which the stiffener 330 is retained, and FIG. 4(C) shows a semiconductor package in which the stiffener 330 is partially removed or partially thinned.

FIGS. 4(D) to 4(F) show exemplary semiconductor packages that can be made from the process as described in FIGS. 3(A) to 3(D) but with modifications to extend to a 2 or more die stack package. For such packages, a plurality of chips 301 with through-silicon interconnects (not shown) may be mounted in vertical stacks onto the support carrier prior to molding. The top-most chip may be a flip chip without the through silicon interconnects. In FIGS. 4(D) to 4(F), the stacked assembly includes a first chip 301 with through silicon interconnects (not shown) and a second chip 302 with conductive bumps 303. Gaps between the first and second chips are filled with an underfill resin 304.

FIG. 4(D) shows a semiconductor package in which the stiffener 330 is completely removed, FIG. 4(E) shows a semiconductor package in which the stiffener 330 is retained, and FIG. 4(F) shows a semiconductor package in which the stiffener 330 is partially removed or partially thinned.

FIGS. 4(G) to 4(I) show further exemplary semiconductor packages that can be made from the process as described in FIGS. 3(A) to 3(D) but with modifications to mount the stiffener 330 directly on the top-most chip 300. For such packages, instead of leaving a space between the top-most chips 300 and the stiffener 330, the stiffener 330 is in contact with the top surface of the chips 300 (optionally through a thermally conductive layer) such that the mold material 320 does not encapsulate the top surface of the chip 300.

FIG. 4(G) shows a semiconductor package in which the stiffener 330 is retained and is in contact with the chip 300, FIG. 4(H) shows a semiconductor package in which the stiffener 330 is partially removed or partially thinned and is in contact with the chip 300, and FIG. 4(I) shows a semiconductor package in which the stiffener 330 is completely removed to expose top surface of the chips 300 to mold material 320.

FIG. 4(J) shows an exemplary semiconductor package having a heterogeneous structure. As previously described, such a package can be assembled by the process as described in FIGS. 3(A) to 3(D) by arranging the chips of different sizes in the required configuration on the support carrier prior to molding.

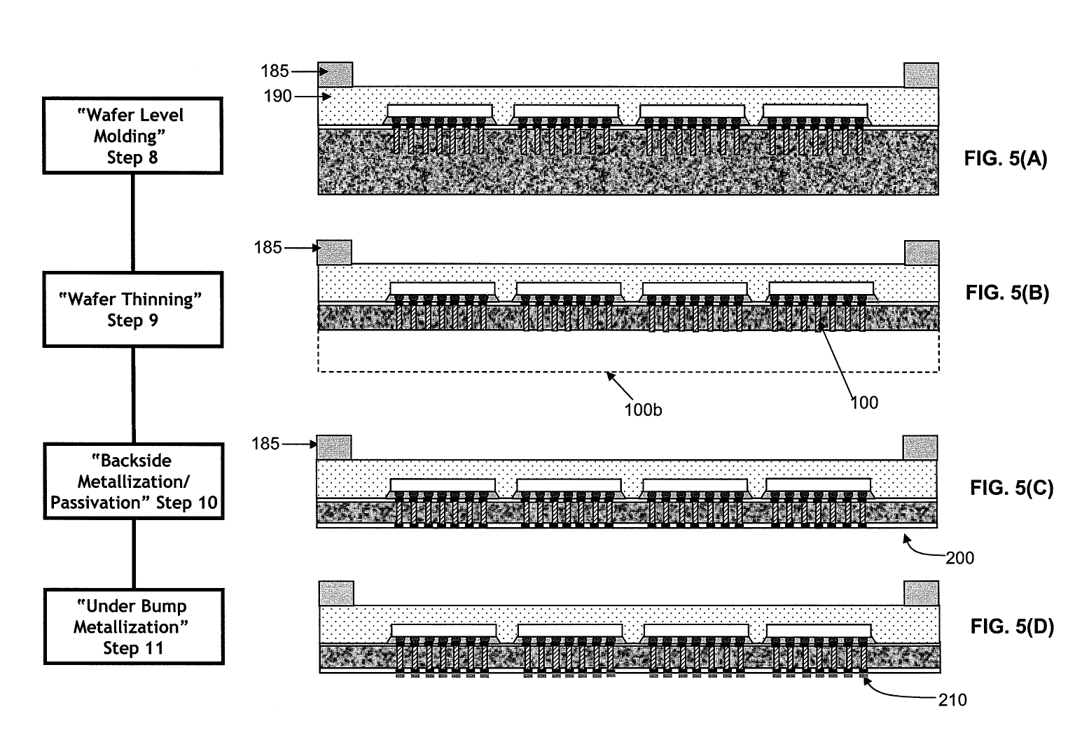

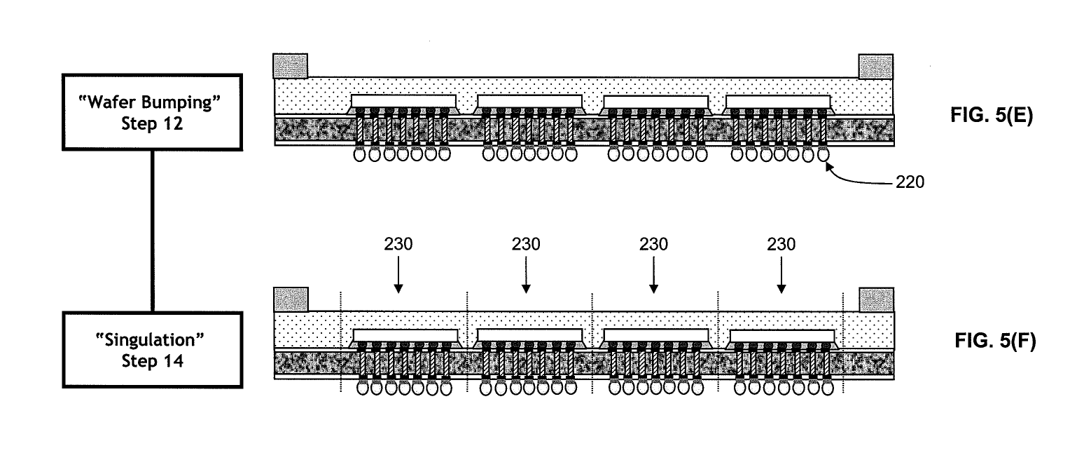

### FIGS. 5(A) to 5(F)

FIGS. 5(A) to 5(F) show an alternative process that can replace Steps 8 to 14 as shown in FIGS. 1(H)-1(N). In this alternative process, the stiffener covers only the peripheral regions of the chip array 160 formed on the wafer 100.

Following steps 1 to 7 as described for FIGS. 1(A) to 1(G), is “Wafer Level Molding” Step 8 as shown in FIG. 5(A). The wafer 100 and the chips 160 are covered with mold material 190 such as an epoxy resin or polymer-based encapsulation material. Before the molding process is carried out, a stiffener 185 is first positioned above the chips 160. The stiffener occupies the peripheral regions of the chip array. Preferably, the stiffener occupies peripheral regions that do not overlap with the locations of the chips 160 as shown in FIG. 5(A). During molding, the mold material 190 will flow into the space between the stiffener 185 and the chips 160 to encapsulate the chips 160. As the mold material 190 cures under heat, the stiffener 185 can prevent the structure from warping resulting from differential thermal expansions of the various components in the structure. The stiffener 185 may be made of silicon, glass or other materials suitable for preventing the warpage.

“Wafer Thinning” Step 9: As shown in FIG. 5(B), the molded wafer 100 from Step (8) is ground and polished at its backside 100b to expose end portions 140a of the through silicon interconnects 140. As will be appreciated, the grinding may be achieved by mechanical grinding methods or chemical etching methods.

“Back Side Metallization/Passivation” Step 10: Referring to FIG. 5(C), back side metallization and passivation are carried out on the thinned wafers 100 from Step 9. The metallization process patterns metal traces and/or bond pads over the back side 100b of the wafer and end portions 140a of the through silicon interconnects 140. The metallic layer used in patterning the metal traces and/or bond pads may be copper, aluminum or other metals. The passivation process coats at least the areas on the back side of the wafer, which are not covered by the metallization layer, with a passivation layer such as silicon nitride, silicon dioxide, polyimide, benzocyclobutene (BCB) or a photosensitive epoxy resin (trade names: “WPR-1020”, “WPR-1050” or “WPR-1201”, products of JSR Micro, Inc.). For ease of illustration, the backside metallization and the passivation layers are collectively given the numeral 200 in the drawings.

“Under bump metallization” Step 11: Under bump metallization (UBM) pads 210 are formed on selected areas of the metallized portions of the wafer 100 from Step 10 as depicted in FIG. 5(D). The selected areas may be locations for mounting conductive bumps in subsequent step 12. The UBM pads 210 may be made of Al/Ni/Au, Al/Ni—V/Cu, Cu/Ni/Au, Cu/Ni/Pd, Cu/Cr/Al, Ti—W/Cu/Ni(EP)/Cu(EP), Cr/Cu/Cu(EP)/Ni(EP), Ti/Ni(EP) or Ti/Ai/Ti/NiV.

“Wafer Bumping” Step 12: With reference to FIG. 5(E), the UBM pads 210 at the back side 100b of the wafer 100 are provided with conductive bumps 220 such as solder interconnects. Other non-solder interconnects include but are not limited to Copper pillars, Gold studs, etc.

“Singulation” Step 14: The bumped wafer and chip structure from Step 12 is singulated into individual units 230, each unit comprising the singulated wafer and chip as shown in FIG. 5(F). Thereafter, Steps 15 and 16 as described above for FIGS. 1(O) and 1(P) would follow. Alternatively, the singulation may be such that the individual units comprises more than one singulated wafer and chips. After singulation, the peripheral regions are removed along with the stiffener. Accordingly, there is no need for “Complete/Partial Removing of Stiffener” Step 13 as shown in FIG. 1(M).

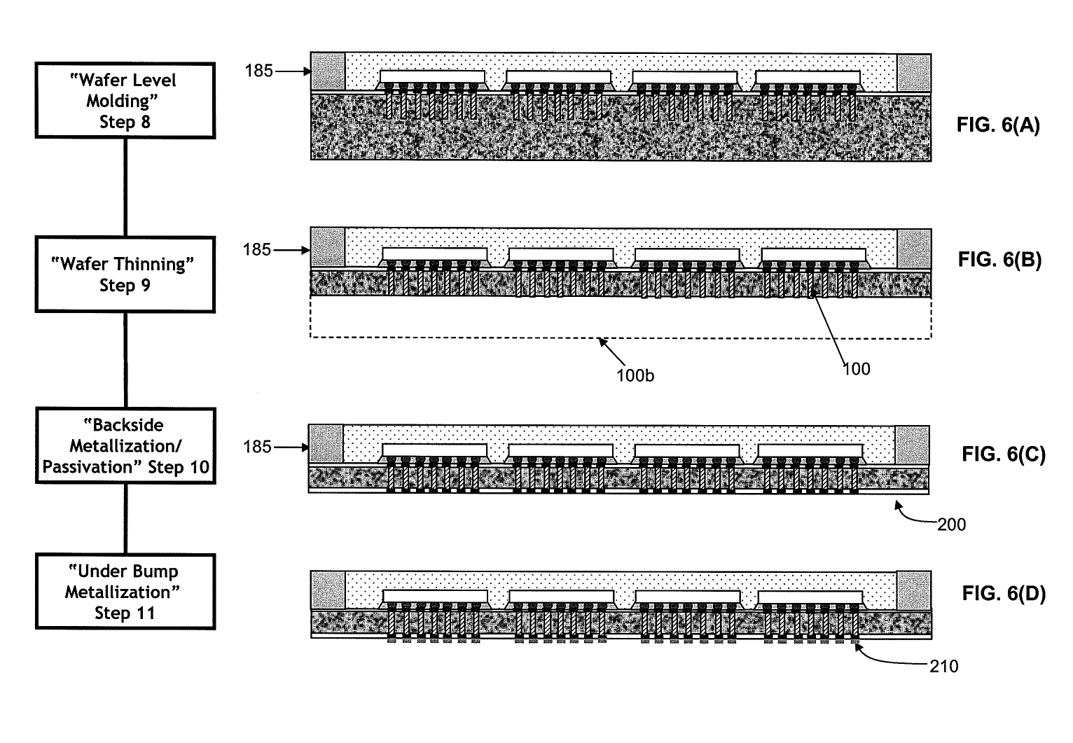

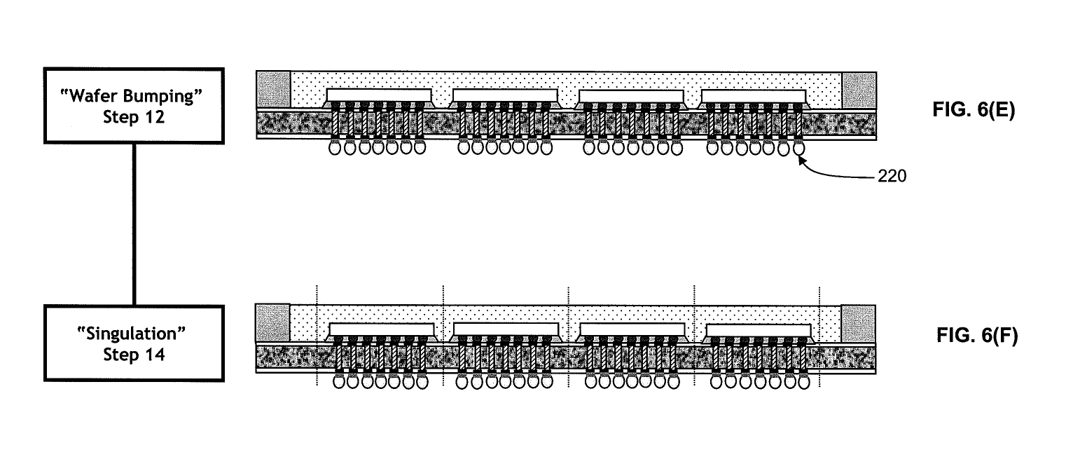

### FIGS. 6(A) to 6(F)

FIGS. 6(A) to 6(F) show an alternative process that can replace Steps 8 to 14 as shown in FIGS. 1(H)-1(N). In this alternative process, the stiffener covers only the peripheral regions of the wafer 100 and is embedded in mold compound 190.

Following steps 1 to 7 as described for FIGS. 1(A) to 1(G), is “Wafer Level Molding” Step 8 as shown in FIG. 6(A). The wafer 100 and the chips 160 are covered with mold material 190 such as an epoxy resin or polymer-based encapsulation material. Before the molding process is carried out, a stiffener 185 is first positioned on the wafer 100. The stiffener occupies the peripheral regions of the wafer 100 and encircles the chips 160 as shown in FIG. 5(A). During molding, the mold material 190 will encapsulates the chips 160 and the stiffener 185. As the mold material 190 cures under heat, the stiffener 185 can prevent the structure from warping resulting from differential thermal expansions of the various components in the structure. The stiffener 185 may be made of silicon, glass or other materials suitable for preventing the warpage.

“Wafer Thinning” Step 9: As shown in FIG. 6(B), the molded wafer 100 from Step (8) is ground and polished at its backside 100b to expose end portions 140a of the through silicon interconnects 140. As will be appreciated, the grinding may be achieved by mechanical grinding methods or chemical etching methods.

“Back Side Metallization/Passivation” Step 10: Referring to FIG. 6(C), back side metallization and passivation are carried out on the thinned wafers 100 from Step 9. The metallization process patterns metal traces and/or bond pads over the back side 100b of the wafer and end portions 140a of the through silicon interconnects 140. The metallic layer used in patterning the metal traces and/or bond pads may be copper, aluminum or other metals. The passivation process coats at least the areas on the back side of the wafer, which are not covered by the metallization layer, with a passivation layer such as silicon nitride, silicon dioxide, polyimide, benzocyclobutene (BCB) or a photosensitive epoxy resin (trade names: “WPR-1020”, “WPR-1050” or “WPR-1201”, products of JSR Micro, Inc.). For ease of illustration, the backside metallization and the passivation layers are collectively given the numeral 200 in the drawings.

“Under bump metallization” Step 11: Under bump metallization (UBM) pads 210 are formed on selected areas of the metallized portions of the wafer 100 from Step 10 as depicted in FIG. 6(D). The selected areas may be locations for mounting conductive bumps in subsequent step 12. The UBM pads 210 may be made of Al/Ni/Au, Al/Ni—V/Cu, Cu/Ni/Au, Cu/Ni/Pd, Cu/Cr/Al, Ti—W/Cu/Ni(EP)/Cu(EP), Cr/Cu/Cu(EP)/Ni(EP), Ti/Ni(EP) or Ti/Ai/Ti/NiV.

“Wafer Bumping” Step 12: With reference to FIG. 6(E), the UBM pads 210 at the back side 100b of the wafer 100 are provided with conductive bumps 220 such as solder interconnects. Other non-solder interconnects include but are not limited to Copper pillars, Gold studs, etc.

“Singulation” Step 14: The bumped wafer and chip structure from Step 12 is singulated into individual units 230, each unit comprising the singulated wafer and chip as shown in FIG. 6(F). Thereafter, Steps 15 and 16 as described above for FIGS. 1(O) and 1(P) would follow. Alternatively, the singulation may be such that the individual units comprises more than one singulated wafer and chips. After singulation, the peripheral regions are removed along with the stiffener.

Accordingly, there is no need for “Complete/Partial Removing of Stiffener” Step 13 as shown in FIG. 1(M).

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method for forming semiconductor packages comprising:
disposing one or more semiconductor chips on a top side of a wafer;
disposing a stiffening layer above the semiconductor chips; and
molding the semiconductor chips with a molding material between the stiffening layer and the wafer.

2. The method of claim 1, further comprising:
curing the molding material;
wherein the stiffening layer provides support to the package during the curing.

3. The method of claim 1, wherein the stiffening layer is silicon or glass.

4. The method of claim 1, wherein the stiffening layer directly contacts the semiconductor chips.

5. The method of claim 1, wherein a thermally conductive layer is provided between the stiffening layer and the top surface of the semiconductor chips.

6. The method of claim 1, wherein a temporary adhesive is provided on the surface of the stiffening layer facing the semiconductor chips.

7. The method of claim 1, wherein the stiffening layer is completely removed from the molding material.

8. The method of claim 8, wherein the removing is performed by mechanical grinding or chemical etching.

9. The method of claim 1, wherein the stiffening layer is partially thinned.

10. The method of claim 9, wherein the thinning is performed by mechanical grinding or chemical etching.

11. The method of claim 1, wherein the stiffening layer covers a top side of the molding material only on a periphery of the wafer.

12. The method of claim 11, wherein the stiffening layer is in the shape of a ring.

13. The method of claim 11, wherein the stiffening layer is in the shape of a square or a rectangle.

14. The method of claim 1, wherein the stiffening layer substantially covers a top side of the molding material.

15. The method of claim 11, wherein the stiffening layer is removed by singulating semiconductor packages on the wafer.

16. A method for forming semiconductor packages comprising:
disposing one or more semiconductor chips on a top side of a wafer;
disposing a stiffening layer in contact with the top side of the wafer only on the periphery of the wafer; and
molding the semiconductor chips with a molding material, the molding material being bounded by an inside-facing surface of the stiffening layer at the periphery of the wafer.

17. The method of claim 16, further comprising:
curing the molding material;
wherein the stiffening layer provides support to the package during the curing.

18. The method of claim 16, wherein the stiffening layer is silicon or glass.

19. The method of claim 16, wherein the stiffening layer is in the shape of a ring.

20. The method of claim 16, wherein the stiffening layer is in the shape of a square or a rectangle.

21. A semiconductor package comprising:
a semiconductor chip disposed on a top side of a portion of a wafer; and
a molding material encapsulating at least the sides of the semiconductor chip, the molding material having been molded between the portion of the wafer and a stiffening layer disposed over the molding material.

22. The semiconductor package of claim 21, wherein:
the stiffening layer substantially covers the molding material.

23. The semiconductor package of claim 22, wherein:
the stiffening layer directly contacts the surface of the semiconductor chips.

24. The semiconductor package of claim 22, wherein:
the stiffening layer has been completely removed from the semiconductor package.

25. The semiconductor package of claim 22, wherein:
the molding material completely encapsulates the semiconductor chip, the molding material having been molded between the portion of the wafer and a stiffening layer disposed over the molding material only at the periphery of the wafer.

26. The semiconductor package of claim 25, wherein:
the stiffening layer has been completely removed by singulation of the semiconductor package.

27. A semiconductor package comprising:
a semiconductor chip disposed on a top side of a portion of a wafer; and
a molding material encapsulating at least the sides of the semiconductor chip, the molding material having been molded in an area above the portion of the wafer bounded by an inside surface of a stiffening layer disposed over the molding material.

28. The semiconductor package of claim 27, wherein:
the stiffening layer has been completely removed by singulation of the semiconductor package.
